(19) United States
(12) Patent Application Publication
(10) Pub. No.: US 2009/0163033 A1
(43) Pub. Date: Jun. 25, 2009

(54) METHODS FOR EXTENDING CHAMBER COMPONENT LIFE TIME

(76) Inventors: GUOWEN DING, San Jose, CA (US); Changhun Lee, San Jose, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/963,432

(22) Filed: Dec. 21, 2007

(51) Int. Cl. H01L 21/3065

(52) U.S. Cl. 438/716; 257/E21.218

(57) ABSTRACT

Methods for extending service life of chamber components for semiconductor processing are provided. In one embodiment, the method includes maintaining a substrate support assembly disposed in a processing chamber at a first temperature, performing a first plasma process on a first substrate in the processing chamber while the substrate support is maintained at the first temperature, and raising the temperature of the substrate support assembly to a second temperature after completion of the first plasma process.

### BACKGROUND

1. Field

Embodiments of the present invention generally relate to the fabrication of integrated circuits. More specifically, embodiments of the invention related to methods of extending the service life of chamber components for semiconductor processing.

2. Description of the Related Art

Ultra-large-scale integrated (ULSI) circuits may include more than one million electronic devices (e.g., transistors) that are formed on a semiconductor substrate, such as a silicon (Si) substrate, and cooperate to perform various functions within the device. Typically, the transistors used in the ULSI circuits are complementary metal-oxide-semiconductor (CMOS) field effect transistors. A CMOS transistor has a gate structure comprising a polysilicon gate electrode and gate dielectric, and is disposed between a source region and drain regions that are formed in the substrate.

Plasma etching is commonly used in the fabrication of transistors and other electronic devices. During plasma etch processes used to form transistor structures, one or more layers of a film stack (e.g., layers of silicon, polysilicon, hafnium dioxide (HfO₂), silicon dioxide (SiO₂), metal materials, and the like) are typically exposed to etchants comprising at least one halogen-containing gas, such as hydrogen bromide (HBr), chlorine (CF₂), boron chlorine (BCl₃), carbon tetrafluoride (CF₄), ethylene (C₂H₄) and the like, supplied in a processing chamber. Such processes cause a halogen containing residue and etching by-products to build up on the surfaces of the substrate as well as chamber components of the processing chamber. The halogen containing etch by-products may also attack the surfaces of the chamber components, which in turn detrimentally affects the ability to maintain process control during circuit fabrication. Furthermore, etching by-products accumulating on components and surfaces of the processing chamber may become a source of unwanted particles that may contaminate the substrate. To maintain cleanliness of the processing chamber, a “wet clean” process is periodically performed after a number of substrates are processed in the processing chamber. The “wet clean” process is used to remove deposition and/or byproduct buildups from the surfaces of the chamber components. However, wet clean processes are labor intensive and require the chamber to be out of service for about several hours, adversely impacting system throughput and increasing manufacturing costs.

Therefore, there is a need for an improved method for removing etching by-products accumulated on the chamber components to increase mean wafers between clean (MWBC) as well as chamber component life time.

### SUMMARY

Embodiments of the present invention generally provide methods for extending service life of chamber components for semiconductor processing. In one embodiment, the method includes maintaining a substrate support assembly disposed in a processing chamber at a first temperature, performing a first plasma process on a first substrate in the processing chamber while the substrate support is maintained at the first temperature, and raising the temperature of the substrate support assembly to a second temperature after completion of the first plasma process.

In another embodiment, a method for extending service life of chamber components for semiconductor processing includes maintaining a temperature of a substrate support assembly disposed in a processing chamber at a first predetermined temperature, performing a first plasma process on a first substrate disposed on the substrate support assembly, wherein the first plasma process is performed at the first temperature, removing the first substrate from the substrate support assembly, and raising the substrate support assembly temperature to a second predetermined temperature after removal of the first substrate from the substrate support assembly and prior to placing another substrate on the substrate support assembly.

In yet another embodiment, a method for extending service life of chamber components for semiconductor processing includes maintaining a temperature of a substrate support assembly having a substrate disposed thereon in a processing chamber at a first predetermined temperature, performing a plasma process on a material layer disposed on the first substrate while the substrate support assembly is maintained at the first temperature, removing the first substrate from the substrate support assembly after etching the material layer, raising the substrate support assembly temperature without a substrate positioned thereon to a second predetermined temperature, and lowering the substrate support assembly temperature to the first predetermined temperature prior to performing a second plasma process.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of an exemplary plasma reactor in which at least one embodiment of the invention may be practiced;

FIG. 2 is a flow diagram of one embodiment of an etching process according to one embodiment of the invention; and

FIGS. 3A-C are temperature variation of a substrate support assembly disposed in the plasma reactor of FIG. 1 during the etching process of FIG. 2.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the present invention provide methods for extending service life of chamber components for semiconductor processing using a post etch clean process. In one embodiment, the method includes raising a temperature of a substrate support assembly disposed in a processing chamber in absence of a substrate (e.g., during in-situ chamber cleaning or during substrate transfer) to assist evaporating plasma by-products that may be present in the processing chamber. The raising of the substrate support assembly temperature after the substrate has been removed prevents the etching by-products from being accumulating on the chamber components, which enables a good control of etching process conditions while inhibiting process drift. Thus, by raising the temperature of the substrate support assembly to reduce and/or remove the amount of deposited etch by-products, the need for periodical offline cleaning of the processing chamber is diminished, thereby allowing the mean wafers between clean (MWBC) to be extended.

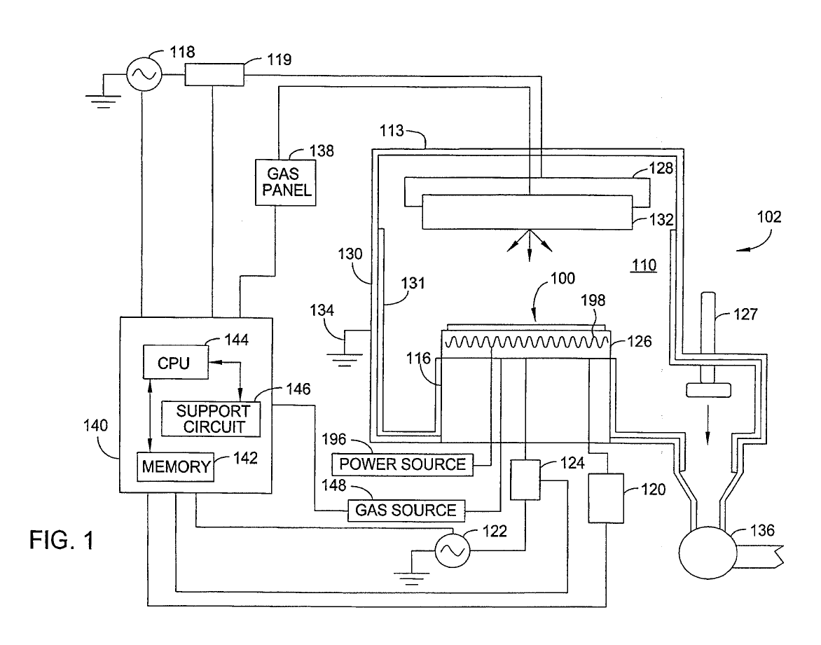

FIG. 1 depicts a schematic, cross-sectional diagram of one embodiment of a plasma source etch reactor 102 suitable for practicing at least one embodiment of the invention. One such etch reactor suitable for performing the invention is Decoupled Plasma Source (DPS), DPS-II, DPS-II AdvantEdge HT, DPS Plus, or DPS DT, Enabler, HART, a HART TS, and all other different types of etch reactor, all available from Applied Materials, Inc. of Santa Clara, Calif. It is contemplated that the post etch clean process described herein may be performed in other etch reactors, including those from other manufacturers.

In one embodiment, the reactor 102 includes a process chamber 110. The process chamber 110 is a high vacuum vessel that is coupled through a throttle valve 127 to a vacuum pump 136. The process chamber 110 includes a conductive chamber wall 130 and a lid 113. The temperature of the chamber wall 130 is controlled using liquid-containing conduits (not shown) that are located in and/or around the wall 130 and/or lid 113. The chamber wall 130 is connected to an electrical ground 134. A liner 131 is disposed in the chamber 110 to cover the interior surfaces of the walls 130. The liner 131 facilitates in-situ self-cleaning capabilities of the chamber 110, so that by-products and residues deposited on the liner 131 can be readily removed.

The process chamber 110 also includes a substrate support assembly 116 and one or more gas injection nozzles or showerhead. The process chamber 110 is shown with a showerhead 132 in FIG. 1. The substrate support assembly 116 is disposed below the showerhead 132 in a spaced-apart relation. The substrate support assembly 116 may include an electrostatic chuck 126 for retaining a substrate 100 during processing. Power to the electrostatic chuck 126 is controlled by a DC power supply 120.

The substrate support assembly 116 is coupled to a radio frequency (RF) bias power source 122 through a matching network 124. The bias power source 122 is generally capable of producing a bias power of about 0 to 3,000 Watts. Optionally, the bias power source 122 may be a DC or pulsed DC source.

The temperature of the substrate 100 supported on the substrate support assembly 116 is at least partially controlled by regulating the temperature of the substrate support assembly 116. In one embodiment, the substrate support assembly 116 includes a channels formed therein for flowing a coolant. In addition, a backside gas, such as helium (He) gas, provided from a gas source 148, fits provided into channels disposed between the back side of the substrate 100 and grooves (not shown) formed in the surface of the electrostatic chuck 126. The backside He gas provides efficient heat transfer between the pedestal 116 and the substrate 100.

The substrate support assembly 116 also includes one or more heating elements, such as lamps, resistive heaters, conduits for circulating heat transfer fluid, and the like. In one embodiment, the heating element is a resistive heater 198 embedded in the electrostatic chuck 126. The resistive heater 198 is coupled to a power source 196 to control the temperature of the substrate support assembly 116 (e.g., including the substrate supporting surface of the electrostatic chuck 126 during and/or between substrate processing.

The showerhead 132 is mounted to the lid 113 of the processing chamber 110. A gas panel 138 is fluidly coupled to a plenum (not shown) defined between the showerhead 132 and the lid 113. The showerhead 132 includes a plurality of holes to allow gases provided to the plenum from the gas panel 138 to enter the interior volume of the process chamber 110.

The showerhead 132 and/or an upper electrode 128 positioned proximate thereto is coupled to an RF source power 118 through an impedance transformer 119 (e.g., a quarter wavelength matching stub). The RF source power 118 is generally capable of producing a source power of about 0 to 5,000 Watts.

During substrate processing, gas pressure within the interior of the chamber 110 is controlled using the gas panel 138 and the throttle valve 127. In one embodiment, the gas pressure within the interior of the chamber 110 is maintained at about 0.1 to 999 mTorr. The substrate 100 may be maintained at a temperature of between about 10 to about 200 degrees Celsius during processing.

A controller 140, including a central processing unit (CPU) 144, a memory 142, and support circuits 146, is coupled to the various components of the reactor 102 to facilitate control of the processes of the present invention. The memory 142 can be any computer-readable medium, such as random access memory (RAM), read only memory (ROM), floppy disk, hard disk, or any other form of digital storage, local or remote to the reactor 102 or CPU 144. The support circuits 146 are coupled to the CPU 144 for supporting the CPU 144 in a conventional manner. These circuits include cache, power supplies, clock circuits, input/output circuitry and subsystems, and the like. A software routine or a series of program instructions stored in the memory 142, when executed by the CPU 144, causes the reactor 102 to perform an etch process of the present invention.

FIG. 1 only shows one exemplary configuration of various types of plasma reactors that can be used to practice the invention. For example, different types of source power and bias power can be coupled into the plasma chamber using different coupling mechanisms. Using both the source power and the bias power allows independent control of a plasma density and a bias voltage of the substrate with respect to the plasma. In some applications, the plasma may be generated in a different chamber from the one in which the substrate is located, e.g., remote plasma source, and the plasma subsequently guided into the chamber using techniques known in the art.

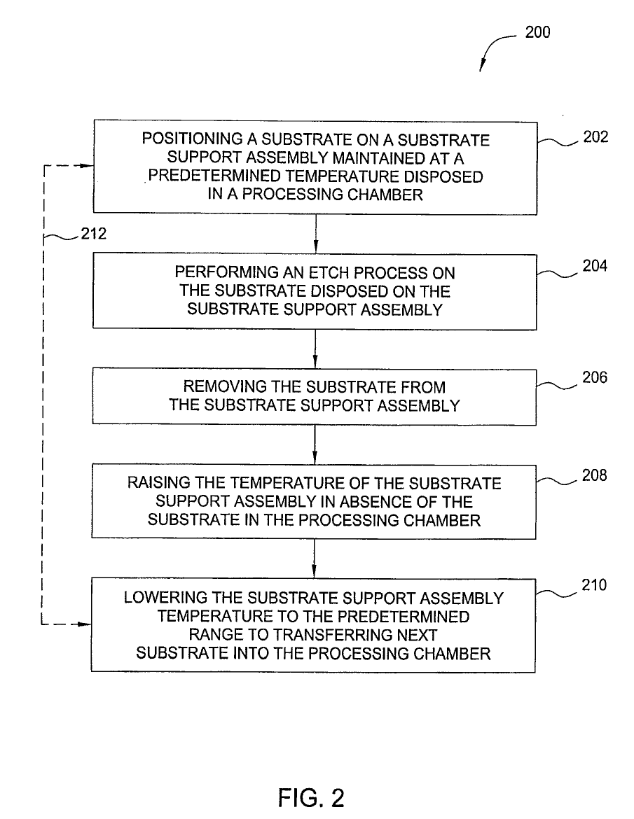

FIG. 2 illustrates a flow diagram of one embodiment of an process 200 of etching a material layer which incorporates a post etch clean process according to one embodiment of the invention. The process 200 may be stored in memory 142 as instructions that executed by the controller 140 to cause the process 200 to be performed in a plasma processing chamber, such as the reactor 102 or other suitable etch reactor.

The process 200 begins at a block 202 by providing a substrate in a processing chamber. The substrate may be any substrate or material surface upon which film processing is performed. In one embodiment, the substrate may have a material layer or material layers formed thereon utilized to form a structure, such as a gate structure, an interconnection structure, or a dual damascene structure. The material layer may be a dielectric layer, a metal layer, or any other suitable materials. In one embodiment, the material layer is a metal layer, such as aluminum, aluminum alloy, tungsten, copper, and the like. In an exemplary embodiment, the material layer is aluminum metal. The substrate may include a mask layer utilized as an etch mask to facilitate the fabrication of features or structures in the material layer. In another embodiment, the substrate may have multiple material layers, e.g., a film stack, utilized to form different patterns and/or features, such as interconnection or dual damascene structure and the like. In one embodiment, the material layers disposed on the substrate to be etched may include photoresist layer, hard mask layer, bottom anti-reflective coating (BARC), such as titanium nitride (TiN), tantalum nitride (TaN), tantalum silicon nitride (TaSiN) and metal materials, such as titanium (Ti), tantalum (Ta) aluminum (Al), copper (Cu), and tungsten (W), among others. Suitable examples of hard mask layer include silicon oxynitride (SiON), silicon nitride, TEOS, silicon oxide, amorphous carbon, and silicon carbide.

The substrate may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire, metal layers disposed on silicon and the like. The substrate may have various dimensions, such as 200 mm or 300 mm diameter wafers, as well as, rectangular or square panels.

At block 204, an etching process is performed on the substrate to form features in the material layer. The etching process is performed by supplying an etching gas mixture suitable for etching the material layer into the processing chamber. In one embodiment, the etching gas mixture supplied at block 204 includes a halogen containing gas. The halogen containing gas is used to provide reactive etchants for etching the material layer. Suitable examples of the halogen containing gas include at least one of CF₄, C₂F₆, HBr, BCl₃, Cl₂, or HCl. In another embodiment, the halogen containing gas used to etch the material layer includes a mixture of BCl₃ and Cl₂ gas. Additionally, other process gases may also be supplied with the halogen containing gas to etch the material layer. Suitable examples of the process gases include a nitrogen containing gas, such as N₂ and NH₃, an unsaturated hydrocarbon gas such as C₂H₄, C₃H₆, C₄H₈, and the like, and an inert gas, such as Ar or He. In one embodiment, the material layer disposed on the substrate is an aluminum layer and the gas mixture used to etch the aluminum layer includes BCl₃, Cl₂, C₂H₄, N₂ and He.

Several process parameters may be regulated during the etching process. In one embodiment, the substrate disposed on the substrate support assembly may be maintained between about 10 degrees Celsius and about 120 degrees Celsius, for example, between about 20 degrees Celsius and about 55 degrees Celsius, such as between about 30 degrees Celsius and about 50 degrees Celsius. In an exemplary embodiment, the substrate temperature disposed on the substrate support assembly is maintained at a temperature about 40 degrees Celsius during plasma etching processing. A pressure of the gas mixture in the processing chamber is regulated between about 5 mTorr to about 200 mTorr, for example, between about 10 mTorr to about 30 mTorr.

At block 206, after completion of the etching process, the substrate is removed from the substrate support assembly. While the substrate is removed from the substrate support assembly and further removed from the processing chamber, an optional in-situ cleaning processing may be performed in the processing chamber during substrate transfer period, e.g, while substrates are absent from the processing chamber, to assist cleaning the etching by-products from the processing chamber. The optional in-situ cleaning processing may be a plasma cleaning process conventionally used in the art. The optional in-situ cleaning processing may be performed after a number of substrates have been processed in the processing chamber. Alternatively, the optional in-situ cleaning processing may be performed after each substrate has been processed in the processing chamber. The substrate support assembly may be maintained at temperature, e.g, such as a temperature utilized for performing etching process, while performing the optional in-situ cleaning processing.

At block 208, during the period wherein the substrate is absent from the substrate support assembly, the temperature of the substrate support assembly is raised from the processing temperature for a post-etch clean process. In one embodiment, the substrate support assembly temperature is increased to a temperature within a range of about 55 degrees Celsius to about 100 degrees Celsius, such as between about 60 degrees Celsius and about 95 degrees Celsius, for example, at about 80 degrees Celsius. The hot substrate support at block 208 promotes the removal of by-products deposited on chamber and substrate support assembly surfaces during the etching process performed at block 204. By-products may include the etched materials combined with the components of the etchant chemistry, as well as with the components of the mask layers. It is believed that the etching by-product deposition rate has a reversed exponential relationship with the process temperature. By increasing the substrate support assembly temperature, some or all of the etching by-product deposition may be removed by transforming the deposited by-products into a gas phase. The etching by-products in form of volatile gases are readily pumped out of the processing chamber instead of building up and/or depositing on the chamber components, where they become a potential source of chamber component and substrate contamination. In one embodiment, the substrate support assembly temperature is raised at least about 10 degrees Celsius more than the temperature utilized during substrate processing. In another embodiment, the substrate support assembly temperature is increased from an etching process set point temperature of about 40 to about 60 degrees Celsius, to a post-etch clean set-point temperature of about 80 to about 100 degrees Celsius. It is noted that the etching process set point temperature may be varied based on different process temperature requirements.

Optionally, the process described at blocks 206 and 208 may be performed simultaneously. It is also contemplated that the performance of the processes 206 and 208 may occur in any order and be performed during overlapping time periods.

At block 210, the substrate support assembly temperature is returned to the original substrate processing temperature for etching the next substrate as described at block 204. In one embodiment, the temperature of the substrate support assembly is lowered to the predetermined processing temperature range prior to the next substrate deposited on the substrate support assembly for plasma processing. Alternatively, the lower temperature setting for the substrate support assembly to be returned to may be varied in accordance with the desired process temperature arranged to perform on the next substrate. Furthermore, the substrate to be processed may be disposed on the substrate support assembly prior to the temperature of the substrate support assembly reaching the processing temperature range.

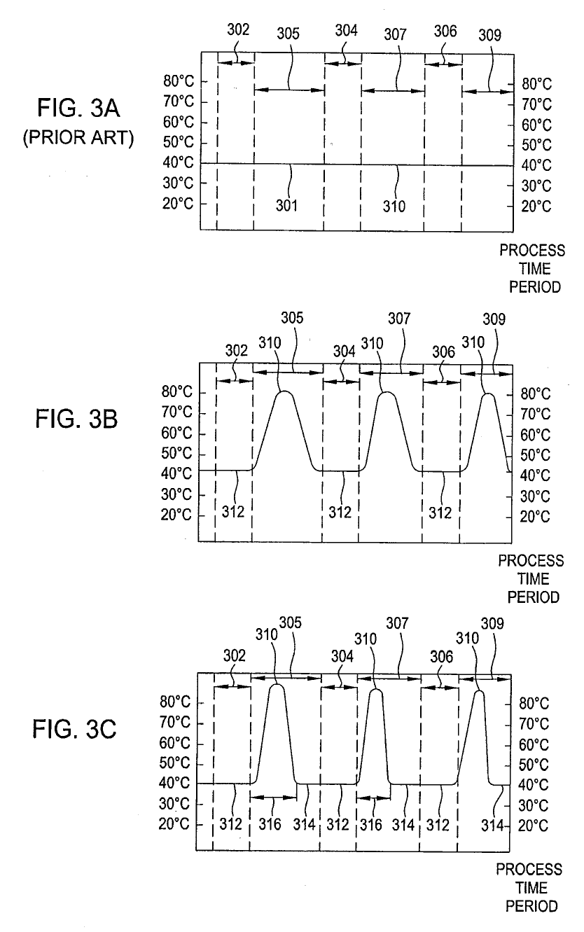

FIG. 3A depicts a graph illustrating the temperature substrate support assembly over the course of a plurality of conventional etching cycles. In conventional techniques, the substrate support assembly temperature remains at a steady set-point temperature 301, such as about 40 degrees Celsius, including periods when substrates are absent from the processing chamber between etch cycles.

FIG. 3B depicts a graph illustrating the temperature of substrate support assembly over a series of plasma processes, such as the process 200 depicted in FIG. 2. During the period 302 wherein a first substrate is provided in the processing chamber for performing a first plasma process, such as the etching process depicted in block 204, the substrate support assembly temperature is maintained at a first predetermined etch set-point temperature, such as about 40 degree Celsius. After completion of the etching process, the first substrate is removed from the substrate support assembly during the period of 305. During the period 305 wherein the substrate is absent from the substrate support assembly, the temperature of the substrate support assembly is raised to a second predetermined post-etch clean set-point temperature 310, such as about 80 degree Celsius, as described in block 208, to promote evaporation of etch by-products. During the period 305 wherein the substrate is absent from the substrate support assembly and further transferred out of the processing chamber, an optional in-situ cleaning process may be performed in the processing chamber. In one embodiment, the temperature of the substrate support assembly may be ramped up and down at a rate between about 1 degrees Celsius per second and about 10 degrees Celsius per second, for example, between about 2 degrees Celsius per second and about 5 degrees Celsius per second. Alternatively, the rate of temperature change may be controlled by setting a final desired set-point temperature to be reached within a desired period of time. For example, the substrate support assembly temperature may be ramped up from a first set-point temperature 312 to a second set-point temperature 310 within between about 10 seconds and about 30 seconds. The substrate support assembly temperature may be remained steadily at the second set-point 310 for a period of time, such as between about 10 seconds to about 60 second, based on different process requirement or different process duration for performing the in-situ chamber cleaning, if necessary. Afterwards, the substrate support assembly temperature may be ramp down to the first set-point temperature 312 within about 10 seconds and about 30 seconds. The total length of the time period 305 is controlled at an appropriate range sufficient to allow the substrate support assembly temperature being ramped up, kept steadily at the desired range, and then further ramped down to the desired set-point temperature, while performing an optional in-situ clean as described in block 206, if necessary, in the processing chamber prior to a next to-be-processed substrate transferring into the chamber. In one embodiment, the amount of time set for ramping up and down the substrate support assembly temperature in the period 305 is controlled between about 40 seconds and about 120 seconds or even longer as needed.

Toward the end of the substrate absence period 305 wherein the substrate support assembly temperature has been ramped down to the original predetermined first set-point temperature 312, a second substrate may be transferred into the processing chamber readily to perform a second plasma process. The substrate support assembly temperature control process 200 may be performed repeatedly, as indicated in the loop 212 during periods of 304, 307, 306, 309 to consecutively performing multiple cycles of the plasma process on multiple substrates without interruption until a desired number of substrates have been processed. As shown in the period of 304, the second substrate is transferred in the processing chamber to perform the second plasma process at the first predetermined set-point temperature 312 of about 40 degree Celsius, as described in block 204 and as performed in period 302. After completion of the etching process, the substrate support assembly temperature is ramped up to the second predetermined set-point temperature 310 of about 80 degrees Celsius during the substrate absence period 307, as in the first substrate during period 305. Similarly, a third substrate may be transferred into the processing chamber at period 306 to be processed at the first predetermined set-point temperature 312 and the substrate support assembly temperature is ramped up in the period 310 while the third substrate has completed the etching process and removed from the processing chamber.

FIG. 3C depicts another embodiment of a graph illustrating the temperature of the substrate support assembly utilizing the method 200 depicted in FIG. 2. Similarly, as discussed above with reference to FIG. 3B, during the period 305, 307, 309 wherein the substrate is absent from the processing chamber, the temperature of the substrate support assembly may be ramped up from the first set-point temperature 312 to the second set-point temperature 310. In one embodiment, the substrate absence period 305, 307, 309 may be divided into two sections 316, 314. The substrate support assembly temperature ramped up and down process may be completed in the first section 316 included in the substrate absence period 305. The temperature of the substrate support assembly is maintained at a first set-point temperature 312 for a predetermined amount of time in the second section 314 of the period 305 to stabilize the temperature of substrate support assembly prior to placing the next substrate to be processed on the substrate support assembly. In one embodiment, the first section 316 in the period 305 is between about 40 seconds and about 110 seconds, and the second section 314 in the period 305 is between about 4 seconds and about 20 seconds.

By adjusting the temperature of the substrate support assembly during the period 305, 307, 309 wherein the substrates are absent from the substrate support assembly, the plasma byproduct accumulation may be efficiently controlled and substantially eliminated. The substrates processed in the processing chamber utilizing the post-etch clean process exhibit predictable process results, good process repeatability and reduced contamination. As the temperature of the substrate support assembly is adjusted in between the substrate process period, e.g., during substrate transfer time, the throughput of the product will not be adversely impacted and process parameters performed on the substrate will not be adversely affected. Additionally, as the accumulation of etching by-products are efficiently controlled and substantially eliminated, the frequency of “wet-clean” process as utilized to clean by-product buildup may be reduced, thereby increasing the mean wafers between clean (MWBC). The increased mean wafers between clean (MWBC) results to increased tool production capacity and greater process control and higher process yield.

It is contemplated that the process 200 as described above may be adapted to benefit maintaining chamber cleanliness for processes other than etching. Suitable examples of other processes include CVD, PVD, ion implantation, ashing, nitration or other suitable plasma or non-plasma semiconductor fabrication process or other process wherein the process is performed at a temperature that promotes condensation of process by-products where the temperature may be raised to a temperature that promotes evaporation of condensed or otherwise deposited recess by-products between process cycles.

Thus, the present application provides methods for extending the service life of chamber components for semiconductor or other processing. The methods advantageously increase the mean wafers between clean (MWBC), thereby minimizing process byproduct contamination of the substrate support assembly and processing system and, thus, promotes robust product yields with long service life of system components.

While the foregoing is directed to embodiments of the present invention, other and further embodiments of the invention may be devised without departing from the basic scope thereof, and the scope thereof is determined by the claims that follow.

1. A method of extending chamber component life time in semiconductor processing, comprising:
(a) maintaining a substrate support assembly disposed in a processing chamber at a first temperature;
(b) performing a first plasma process on a first substrate in the processing chamber while the substrate support is maintained at the first temperature; and
(c) raising the temperature of the substrate support assembly to a second temperature after completion of the first plasma process.

2. The method of claim 1, further comprising:
(d) lowering the substrate support assembly temperature to the first temperature prior to performing a second plasma process.

3. The method of claim 2, further comprising:
repeating (b)-(d).

4. The method of claim 2, wherein lowering the substrate support assembly temperature further comprises:
lowering the substrate support assembly temperature to the first temperature prior to transferring a second substrate into the processing chamber.

5. The method of claim 2, wherein lowering the substrate support assembly temperature further comprises:
stabilizing the substrate support assembly temperature at the first temperature prior to performing the second plasma process in the processing chamber.

6. The method of claim 5, wherein the second plasma process is performed on a second substrate disposed on the substrate support assembly while maintaining the substrate support assembly temperature at the first temperature.

7. The method of claim 1, wherein raising the substrate support assembly temperature further comprises:
removing the first substrate from the substrate support assembly prior to raising the temperature of the substrate support assembly.

8. The method of claim 1, wherein raising the substrate support assembly temperature further comprises:
raising the substrate support assembly temperature to the second predetermined temperature in absent of a substrate on the substrate support assembly.

9. The method of claim 2 further comprising:
performing a in-situ cleaning process in the processing chamber after (b) and before performing a second plasma process.

10. The method of claim 1, wherein the first plasma processing is an etching process.

11. The method of claim 1, wherein the first temperature is between about 20 degrees Celsius and about 60 degrees Celsius and the second temperature is between about 60 degrees Celsius and about 100 degrees Celsius.

12. The method of claim 1, wherein the second temperature is at least 10 degrees Celsius greater than the first temperature.

13. The method of claim 1, wherein the first plasma processing is performed to etch a metal layer disposed on the first substrate.

14. The method of claim 1, wherein the step of raising the substrate support assembly temperature further comprises;
evaporating at least a portion of plasma by-products generated during the first plasma process.

15. A method of extending chamber component life time in semiconductor processing, comprising:
(a) maintaining a temperature of a substrate support assembly disposed in a processing chamber at a first predetermined temperature;
(b) performing a first plasma process on a first substrate disposed on the substrate support assembly, wherein the first plasma process is performed at the first temperature;
(c) removing the first substrate from the substrate support assembly; and
(d) raising the substrate support assembly temperature to a second predetermined temperature after removal of the first substrate from the substrate support assembly and prior to placing another substrate on the substrate support assembly.

16. The method of claim 15, further comprising:
(e) lowing the substrate support assembly temperature to the first predetermined temperature after (d) and prior to placing another substrate on the substrate support assembly.

17. The method of claim 16, further comprising:
(f) transferring a second substrate onto the substrate support assembly and perform a second plasma process on the second substrate after (e).

18. The method of claim 17, further comprising:
performing an in-situ plasma clean process between (b) and (f).

19. A method of extending chamber component life time in semiconductor processing, comprising:
(a) maintaining a temperature of a substrate support assembly having a substrate disposed thereon in a processing chamber at a first predetermined temperature;
(b) performing a plasma process on a material layer disposed on the first substrate while the substrate support assembly is maintained at the first temperature;
(c) removing the first substrate from the substrate support assembly after etching the material layer;
(d) raising the substrate support assembly temperature without a substrate positioned thereon to a second predetermined temperature; and
(e) lowering the substrate support assembly temperature to the first predetermined temperature prior to performing a second plasma process.

20. The method of claim 19, wherein the second plasma etch process is plasma etch process performed on a second substrate.
